(19) United States
(12) Patent Application Publication
(10) Pub. No.: US 2013/0145989 A1
(43) Pub. Date: Jun. 13, 2013

(54) SUBSTRATE PROCESSING TOOL SHOWERHEAD

(71) Applicant: Peter Satitpunwaycha, Sunnyvale, CA (US)

(72) Inventor: Peter Satitpunwaycha, Sunnyvale, CA (US)

(73) Assignee: Intermolecular, Inc., San Jose, CA (US)

(21) Appl. No.: 13/323,281

(22) Filed: Dec. 12, 2011

(51) Int. Cl. C23C 16/455; B67D 7/06

(52) U.S. Cl. 118/724; 118/715; 222/129

(57) ABSTRACT

Embodiments provided herein describe substrate processing tools and showerheads. A substrate processing tool includes a housing defining a processing chamber. A substrate support is coupled to the housing and configured to support a substrate within the processing chamber. A showerhead is coupled to the housing and positioned within the processing chamber above the substrate support. The showerhead includes a dielectric material and has a first surface with a plurality of fluid outlets, a second surface with a plurality of fluid ports, and first and second passageways extending therethrough. The first passageway is in fluid communication with the plurality of fluid outlets and a first of the plurality of fluid ports. The second passageway is in fluid communication with a second and a third of the fluid ports.

The present invention relates to systems and methods for processing substrates. More particularly, this invention relates to a showerhead for a substrate processing tool.

### BACKGROUND OF THE INVENTION

Chemical Vapor Deposition (CVD) is a vapor based deposition process commonly used in semiconductor manufacturing including but not limited to the formation of dielectric layers, conductive layers, semiconducting layers, liners, barriers, adhesion layers, seed layers, stress layers, and fill layers.

Derivatives of CVD based processes include but are not limited to plasma enhanced chemical vapor deposition (PECVD), high-density plasma chemical vapor deposition (HDP-CVD), sub-atmospheric chemical vapor deposition (SACVD), laser assisted/induced CVD, and ion assisted/induced CVD, metal organic chemical vapor deposition (MOCVD), and atomic layer deposition (ALD).

CVD is typically a thermally driven process whereby the precursor flux(es) is pre-mixed and coincident to the substrate surface to be deposited upon. CVD requires control of the substrate temperature and the incoming precursor flux(es) to achieve desired film materials properties and thickness uniformity. Typically, two types of flux are delivered to the substrate through a device referred to as a “showerhead,” which allows the different types of flux to remain separated until they are within relatively close proximity to the substrate, where ideally they are mixed uniformity across the substrate. In order to maximize control of the deposition process, it is desirable to position the showerhead as close to the substrate as possible. However, in conventional systems, when the substrate is inductively heated, the temperature within the showerhead may also rise, causing undesirable reactions of the flux within.

### BRIEF DESCRIPTION OF THE DRAWINGS

Various embodiments of the invention are disclosed in the following detailed description and the accompanying drawings:

FIG. 1 is an isometric view of a showerhead for a substrate processing tool, according to one embodiment of the present invention, from a lower side thereof;

FIG. 2 is an isometric view of the showerhead of FIG. 1 from an upper side thereof;

FIG. 3 is a cross-sectional view of the showerhead taken along line 3-3 in FIG. 2;

FIG. 4 is a cross-sectional view of the showerhead taken along line 4-4 in FIG. 3; and

FIG. 5 is a schematic block diagram of a substrate processing system according to one embodiment of the present invention.

### DETAILED DESCRIPTION

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

Embodiments described herein provide a showerhead for substrate processing tools and systems, such as those used for chemical vapor deposition (CVD) processing, that allows processing fluids (e.g., reactants) that are sensitive to thermal breakdown to be delivered to the substrate being processed, particularly in systems in which the substrate undergoes inductive heating. According to some embodiments of the present invention, the showerhead is made of a dielectric material and has multiple passageways extending therethrough. One or more of the passageways is used to deliver processing fluid to the substrate through a series of openings on the lower surface of the showerhead. Another of the passageways is isolated from the passageway(s) used to deliver processing fluid and is used to control the temperature of the showerhead by flowing a temperature-controlled coolant therethrough.

In some embodiments, a substrate processing tool is provided. The substrate processing tool includes a housing defining a processing chamber. A substrate support is coupled to the housing and configured to support a substrate within the processing chamber. A showerhead is coupled to the housing and positioned within the processing chamber above the substrate support. The showerhead includes a dielectric material and has a first surface with a plurality of fluid outlets, a second surface with a plurality of fluid ports, and first and second passageways extending therethrough. The first passageway is in fluid communication with the plurality of fluid outlets and a first of the plurality of fluid ports. The second passageway is in fluid communication with a second and a third of the fluid ports. The dielectric material may be silicon carbide, alumina, boron nitride, or a combination thereof.

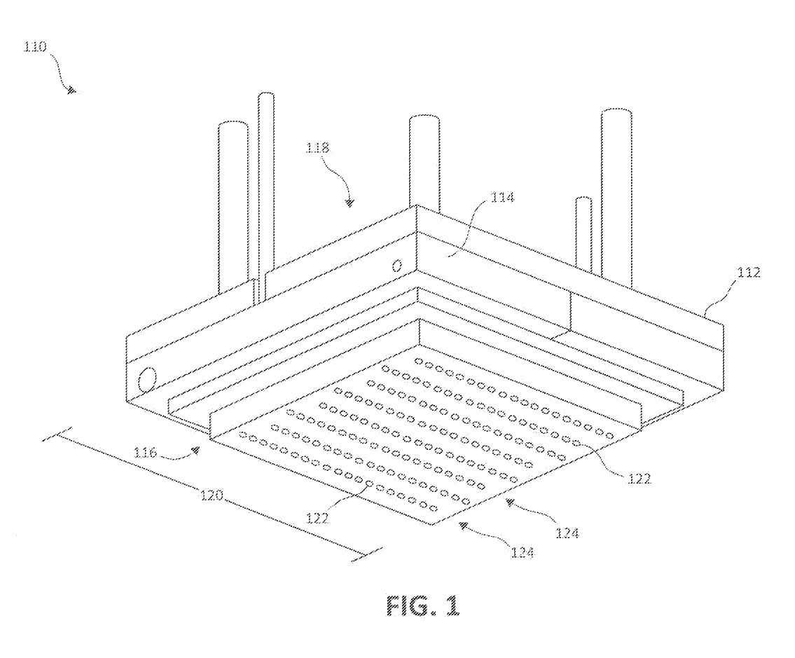

FIG. 1 illustrates a substrate processing tool showerhead 110, according to some embodiments of the present invention. The showerhead 110 includes a body 112 having an outer surface 114 that includes a lower surface (or side) 116 and an upper surface 118. In the example shown, the body 112 is substantially square with a side length 120 of, for example, between 10 and 40 centimeters (cm). However, it should be understood that in other embodiments, the showerhead 110 may be different shapes (e.g., circular) and sizes. The showerhead is, in some embodiments, made of a dielectric material such as silicon carbide, alumina, or boron nitride.

Referring specifically to FIG. 1, the showerhead 110 includes a plurality of fluid outlets (or openings) 122 on the lower surface 116 of the body 112. Although not specifically shown, each of the fluid outlets 122 may have a width of, for example, between 1 and 2 millimeters (mm). The fluid outlets 122 are arranged in a series of rows 124 as shown.

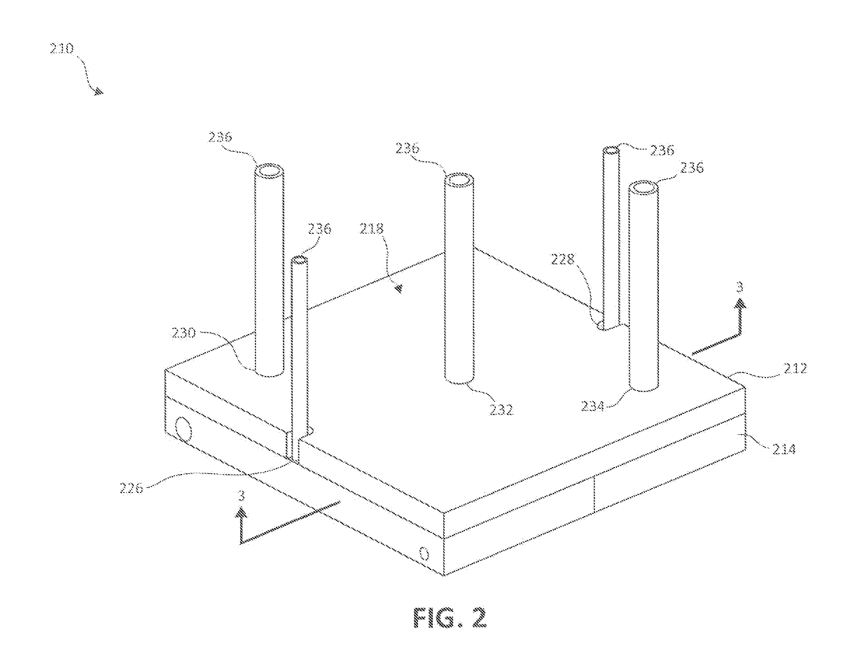

FIG. 2 illustrates the upper surface 218 of the body 212 of the showerhead 210. The showerhead 210 includes fluid ports 226-234 on the upper surface 218. As shown, a portion of tubing 236 is connected to each of the fluid ports 226-234.

In accordance with some embodiments of the present invention, the showerhead further includes multiple passageways extending through the body, which selectively interconnect the fluid outlets 122 (FIG. 1) and the fluid ports 226-234 (FIG. 2) on the outer surface of the body. The passageways are used to deliver processing fluids to a substrate, as well as control the temperature of the showerhead.

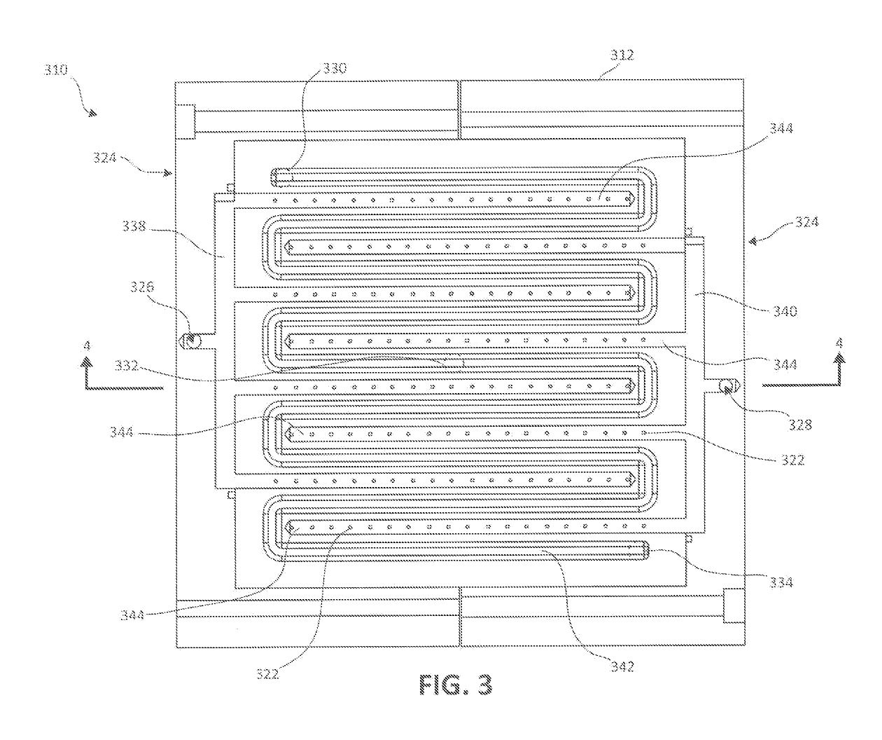

FIG. 3 is a cross-sectional view of the showerhead 310, which may be taken along line 3-3 in FIG. 2. In some embodiments, the showerhead 310 includes a first processing fluid passageway 338, a second processing fluid passageway 340, and a coolant passageway 342 extending through the body 312. As shown, the first processing fluid passageway 338 and the second processing fluid passageway 340 are substantially “comb” shaped and include multiple channels 344 that are arranged in an interleaving or inter-digitated manner. The coolant passageway 342 winds or “snakes” through the portions of the body 312 that are between the inter-digitated channels 344 of the first processing fluid passageway 338 and the second processing fluid passageway 340.

In the embodiment shown in FIG. 3, the first processing fluid passageway 338 is in fluid communication with fluid port 326 (which may correspond to fluid port 226 in FIG. 2) on the upper surface of the body 312, while the second processing fluid passageway 340 is in fluid communication with fluid port 328 (which may correspond to fluid port 228 in FIG. 2) on the upper surface of the body 312. The coolant passageway 342 is in fluid communication with fluid ports 330, 332, and 334 (which may correspond to fluid ports 230, 232, and 234 in FIG. 2) on the upper surface of the body 312. In particular, the coolant passageway 342, at a central portion thereof, is in fluid communication with fluid port 332 and in fluid communication with fluid ports 330 and 334, near respective ends of the coolant passageway 342.

Still referring to FIG. 3, the channels 344 of the first and second processing fluid passageways 338 and 340 are aligned with the rows 324 of the fluid outlets 322 such that the channels 344 of each of the passageways 338 and 340 are in fluid communication with alternating rows 324 of the fluid outlets 322. As such, the fluid outlets 322 may be considered to include two sets of outlets, in which a first set is in fluid communication with the first processing fluid passageway 338 and fluid port 326, and a second set is in fluid communication with the second processing fluid passageway 340 and fluid port 328.

It should also be noted that the first and second processing fluids passageways 338 and 340 are separated from (i.e., not in fluid communication with) each other within the body 312 of the showerhead 310. Additionally, the coolant passageway 342 is separated from the first and second processing fluids passageways 338 and 340.

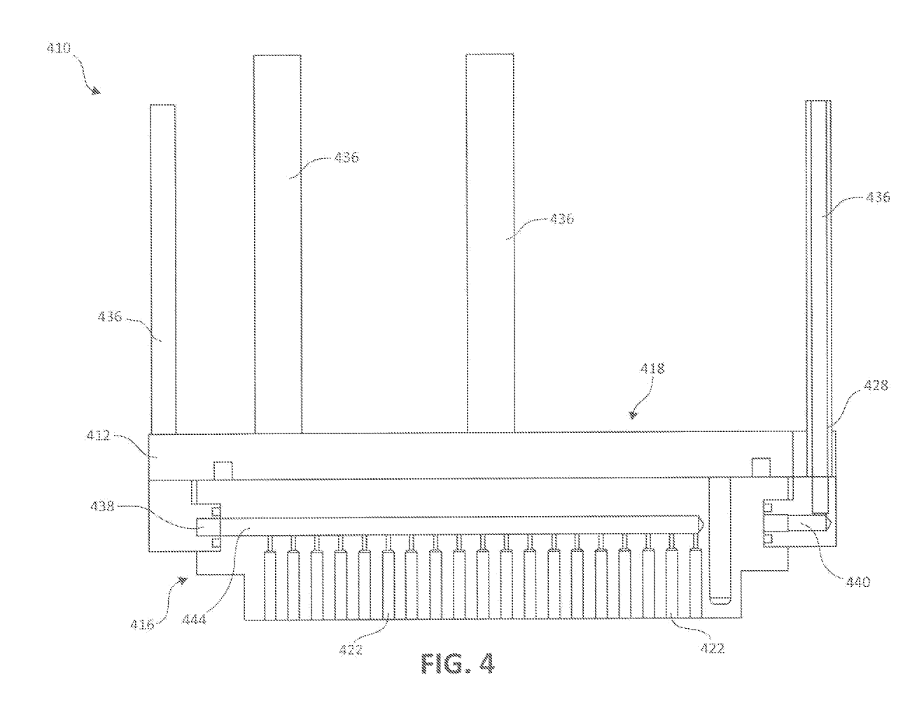

FIG. 4 is a cross-sectional view of the showerhead 410, which may be taken along line 4-4 in FIG. 3. In the view shown in FIG. 4, it can be seen that the first fluid passageway 438 is in fluid communication with the fluid outlets 422 (i.e., within one of the rows of fluid outlets) and the second fluid passageway 440 is in fluid communication with fluid port 428, and the associated portion of tubing 436, on the upper surface 418 of the body 412.

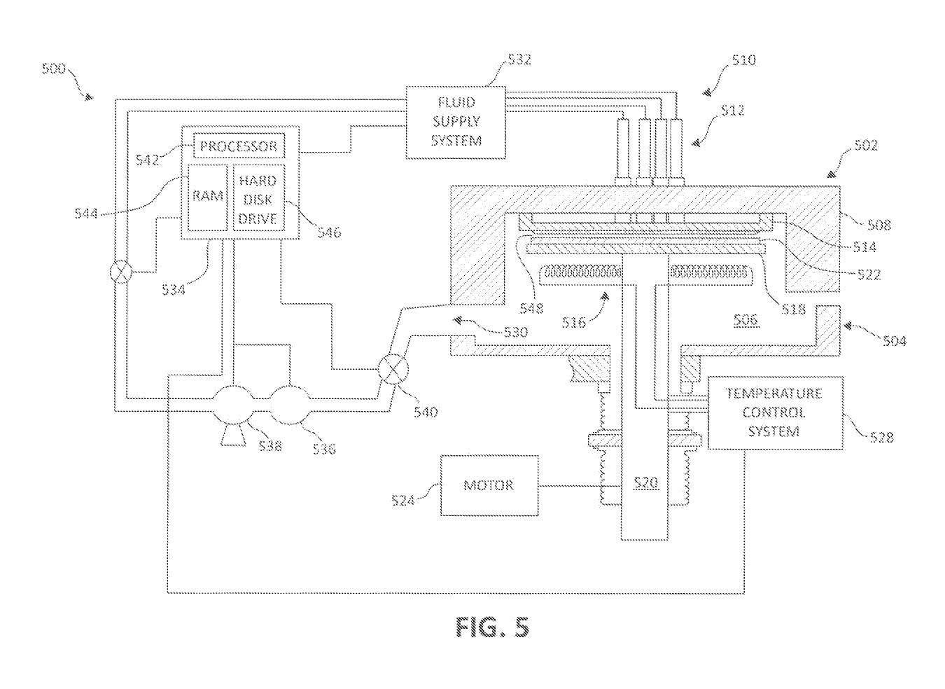

FIG. 5 illustrates a substrate processing system 500 in accordance with some embodiments of the present invention. The processing system 500 may be used to perform, for example, atomic layer deposition (ALD) processing. The substrate processing system 500 includes an enclosure assembly 502 formed from a process-compatible material, such as aluminum or anodized aluminum. The enclosure assembly 502 includes a housing 504, which defines a processing chamber 506, and a vacuum lid assembly 508 covering an opening to the processing chamber 506 at an upper end thereof. Although only shown in cross-section, it should be understood that the process chamber 506 is enclosed on all sides by the housing 504 and/or the vacuum lid assembly 508.

A process fluid injection assembly 510 is mounted to the vacuum lid assembly 508 and includes a plurality of injection ports 512 and a showerhead 514 (e.g., showerhead described above) to deliver reactive and carrier fluids into the processing chamber 506, along with a coolant. The injection ports 512 may be coupled to the portions of tubing on the upper surface of the showerhead as described above.

The processing system 500 also includes a heater/lift assembly 516 disposed within the processing chamber 506. The heater/lift assembly 516 includes a support pedestal (or substrate support) 518 connected to an upper portion of a support shaft 520. The support pedestal 518 may be formed from any process-compatible material, including aluminum nitride and aluminum oxide. The support pedestal 518 is configured to hold or support a substrate 522 such that the channels 344 of the first and second processing fluid passageways 338 and 340 (FIG. 3) within the showerhead 514 are substantially parallel to the upper surface of the substrate 522. The substrate 522 may be, for example, a semiconductor substrate (e.g., silicon) having a diameter of, for example, 200 or 300 mm.

The support pedestal 518 may be a vacuum chuck, as is commonly understood, or utilize other conventional techniques, such as an electrostatic chuck (ESC) or physical clamping mechanisms, to prevent the substrate 522 from moving on the support pedestal 518. The support shaft 520 is moveably coupled to the housing 504 so as to vary the distance between support pedestal 518 and the showerhead 514 using a motor 524.

Additionally, the heater/lift assembly 516 includes an inductive heating sub-system that includes one or more conductive coils (or members) 526 mounted below the support pedestal 518 that are coupled to a power supply within a temperature control system 528.

The housing 504, the support pedestal 518, and the showerhead 514 are sized and shaped to create a peripheral flow channel that surrounds the showerhead 514 and the support pedestal 518 and provides a path for fluid flow to a pump channel 530 in the housing 504.

Still referring to FIG. 5, the processing system 500 also includes a fluid supply system 532 and a controller (or control system) 534. The fluid supply system 532 is in fluid communication with the injection ports 512 through a sequence of conduits (or fluid lines) and includes supplies of various processing fluids (e.g., gases), along with a temperature-controlled coolant (e.g., a liquid, such as water) supply.

The fluid supply system 532 (and/or the controller 534) controls the flow of processing fluids to, from, and within the processing chamber 506 with a pressure control system that includes, in the embodiment shown, a turbo pump 536 and a roughing pump 538. The turbo pump 536 and the roughing pump 538 are in fluid communication with the processing chamber 506 via a butterfly valve 540 through the pump channel 530.

The controller 534 includes a processor 542 and memory, such as random access memory (RAM) 544 and a hard disk drive 546. The controller 534 is in operable communication with the various other components of the processing system 500, including the turbo pump 536, the temperature control system 528, the fluid supply system 532, and the motor 524 and controls the operation of the entire processing system to perform the methods and processes described herein.

During operation, the processing system 500 establishes conditions in a processing region 548 between the upper surface of the substrate 522 on the support pedestal 518 and the showerhead 514 to form a layer of material on the surface of the substrate 522, such as a thin film. The processing technique used to form the material may be, for example, a chemical vapor deposition (CVD) process, such as atomic layer deposition (ALD) or metalorganic chemical vapor deposition (MOCVD). Additionally, it should be noted that the showerhead described herein may also be used in epitaxial processing.

Specifically, referring to FIGS. 3 and 5, the fluid supply system 532 delivers a first processing fluid (e.g., a first reactant gas) to the first processing fluid passageway 338 and a second processing fluid (e.g., a second reactant gas) to the second processing fluid passageway 340. The first and second processing fluids flow from the respective fluid passageways in the showerhead 514 through the lower fluid openings 322 and into the processing region 548. Within the processing region 548, the first and second processing fluids interact in such a way as to deposit a layer of material on the substrate 522, as is commonly understood.

During the formation of the layer, power is provided to the conductive coils 526 by the temperature control system 528 such that current flows through the conductive coils, causing the substrate 522 to be inductively heated. According to some embodiments of the present invention, in order to allow the showerhead 514 to be in close proximity with the substrate 522 (e.g., between 3 and 13 mm), the fluid supply system 532 also delivers (or flows) a temperature-controlled coolant to (or through) the coolant passageway 342 (FIG. 3) within the showerhead 114. For example, the coolant may be delivered to the coolant passageway 342 through fluid port 332 (FIG. 3) in the upper surface of the body 312 and removed from the coolant passageway 342 through fluid ports 330 and 334.

It should also be noted that the dielectric material used for the showerhead further prevents any unwanted heating that may be caused by the inductive heating system. As such, the possibility of an undesired reactions and/or deposition occurring within the showerhead is reduced, while allowing the showerhead to be in close proximity to the substrate, even when the substrate undergoes inductive heating.

Thus, in some embodiments, a substrate processing tool is provided. The substrate processing tool includes a housing defining a processing chamber. A substrate support is coupled to the housing and configured to support a substrate within the processing chamber. A showerhead is coupled to the housing and positioned within the processing chamber above the substrate support. The showerhead includes a dielectric material and has a first surface with a plurality of fluid outlets thereon, a second surface with a plurality of fluid ports thereon, a first passageway extending therethrough and in fluid communication the plurality of fluid outlets and a first of the fluid ports, and a second passageway extending therethrough and in fluid communication with a second and a third of the plurality of fluid ports.

In other embodiments, a showerhead for a substrate processing tool is provided. The showerhead includes a body having an upper surface and a lower surface and a dielectric material. The body also includes a first passageway operable to deliver a first processing fluid extending therethrough and in fluid communication with at least one fluid outlet on the lower surface of the body and a first of a plurality of fluid ports on the upper surface of the body. A second passageway operable to deliver a coolant fluid also extends through the body and is in fluid communication with a second and a third of the plurality of fluid ports on the upper surface of the body. The first passageway is not in fluid communication with the second passageway.

In further embodiments, a substrate processing system is provided. The substrate processing system includes a housing defining a processing chamber. A substrate support is coupled to the housing and configured to support a substrate within the processing chamber. A showerhead is coupled to the housing and positioned within the processing chamber above the substrate support. The showerhead has an upper surface and a lower surface and a dielectric material. The showerhead also includes a first passageway operable to deliver a processing fluid extending therethrough, a second passageway operable to deliver a coolant fluid extending therethrough, a plurality of fluid outlets on the lower surface, and a plurality of fluid ports on the upper surface. The first passageway is in fluid communication with the plurality of fluid outlets and a first of the plurality of fluid ports. The second passageway is in fluid communication with a second and a third of the plurality of fluid ports. At least one processing fluid supply is in fluid communication with the first fluid port. A temperature-controlled coolant supply in fluid communication with the second fluid port.

Although the foregoing examples have been described in some detail for purposes of clarity of understanding, the invention is not limited to the details provided. There are many alternative ways of implementing the invention. The disclosed examples are illustrative and not restrictive.

What is claimed:

1. A substrate processing tool comprising:
a housing defining a processing chamber;
a substrate support coupled to the housing and configured to support a substrate within the processing chamber; and
a showerhead coupled to the housing and positioned within the processing chamber above the substrate support, the showerhead comprising a dielectric material and having a first surface with a plurality of fluid outlets thereon, a second surface with a plurality of fluid ports thereon, a first passageway extending through the showerhead and in fluid communication with one or more of the plurality of fluid outlets and a first of the fluid ports, and a second passageway extending within the showerhead and in fluid communication with a second and a third of the plurality of fluid ports.

2. The substrate processing tool of claim 1, wherein the plurality of fluid outlets comprises a first set of fluid outlets and a second set of fluid outlets, wherein the first passageway is in fluid communication with the first set of fluid outlets, and wherein the showerhead further comprises a third passageway extending through the showerhead and in fluid communication with the second set of outlets and a fourth of the plurality of fluid ports.

3. The substrate processing tool of claim 2, wherein the first passageway is not in fluid communication with the second passageway within the showerhead.

4. The substrate processing tool of claim 3, wherein the second passageway is not in fluid communication with third passageway within the showerhead.

5. The substrate processing tool of claim 4, wherein the first passageway and the third passageway each comprises a plurality of channels, and wherein the plurality of channels of the first passageway and the plurality of channels of the third passageway are inter-digitated.

6. The substrate processing tool of claim 5, further comprising a first processing fluid supply in fluid communication with the first of the plurality of fluid ports and a second processing fluid supply in fluid communication with the fourth of the plurality of fluid ports.

7. The substrate processing tool of claim 6, further comprising a temperature-controlled coolant supply in fluid communication with the second of the plurality of fluid ports.

8. The substrate processing tool of claim 1, further comprising:
a plurality of conductive members coupled to the housing and positioned below the substrate support; and
a power supply coupled to the conductive members and configured to cause a current to flow through the conductive members.

9. The substrate processing tool of claim 8, wherein the dielectric material comprises silicon carbide, alumina, boron nitride, or a combination thereof.

10. The substrate processing tool of claim 5, wherein the plurality of channels of the first passageway and the third passageway extend in a direction that is substantially parallel to an upper surface of the substrate support.

11. A showerhead for a substrate processing tool comprising:
a body having an upper surface and a lower surface and comprising a dielectric material, the body further comprising
a first passageway extending through the body and operable to deliver a first processing fluid and in fluid communication with at least one fluid outlet on the lower surface of the body, and in fluid communication with a first of a plurality of fluid ports on the upper surface of the body, and
a second passageway extending within the body and operable to deliver coolant fluid and in fluid communication with a second and a third of the plurality of fluid ports on the upper surface of the body,
wherein the first passageway is not in fluid communication with the second passageway.

12. The showerhead of claim 11, wherein the body further comprises a third passageway extending through the body and operable to deliver a second processing fluid and in fluid communication with the at least one fluid outlet on the lower surface of the body and a fourth of the plurality of fluid ports on the upper surface of the body, wherein the third passageway is not in fluid communication with the first passageway within the body.

13. The showerhead of claim 12, wherein the at least one fluid outlet comprises a first set of fluid outlets and a second set of fluid outlets.

14. The showerhead of claim 13, wherein the first set of fluid outlets is in fluid communication with the first passageway, and the second set of fluid outlets is in fluid communication with the third passageway.

15. The showerhead of claim 14, wherein the first passageway and the third passageway each comprises a plurality of channels, and wherein the plurality of channels of the first passageway and the plurality of channels of the third passageway are inter-digitated.

16. A substrate processing system comprising:
a housing defining a processing chamber;
a substrate support coupled to the housing and configured to support a substrate within the processing chamber;
a showerhead coupled to the housing and positioned within the processing chamber above the substrate support, the showerhead having an upper surface and a lower surface and comprising a dielectric material, the showerhead further comprising a first passageway extending through the showerhead and operable to deliver a first processing fluid, a second passageway extending within the showerhead and operable to deliver a coolant fluid, a plurality of fluid outlets on the lower surface, and a plurality of fluid ports on the upper surface, wherein the first passageway is in fluid communication with the plurality of fluid outlets and a first of the plurality of fluid ports, and the second passageway is in fluid communication with a second and a third of the plurality of fluid ports;
at least one processing fluid supply in fluid communication with the first fluid port; and
a temperature-controlled coolant supply in fluid communication with the second fluid port.

17. The substrate processing system of claim 16, further comprising:
a plurality of conductive members coupled to the housing and positioned below the substrate support; and
a power supply coupled to the conductive members and configured to cause a current to flow through the conductive members.

18. The substrate processing system of claim 17, wherein the showerhead further comprises a third passageway extending through the showerhead and operable to deliver a second processing fluid and in fluid communication with the plurality of fluid outlets and a fourth of the plurality of fluid ports on the upper surface, wherein the third passageway is not in fluid communication with the first passageway within the body.

19. The substrate processing system of claim 18, wherein the first passageway and the third passageway each comprises a plurality of channels, and wherein the plurality of channels of the processing fluid passageway and the plurality of channels of the second processing fluid passageway are inter-digitated.

20. The substrate processing system of claim 19, wherein the dielectric material comprises silicon carbide, alumina, boron nitride, or a combination thereof.
